(19) United States
(12) Patent Application Publication
(10) Pub. No.: US 2002/0149067 A1
(43) Pub. Date: Oct. 17, 2002

(54) Isolated high voltage MOS transistor

(76) Inventors: Jozef C. Mitros, Richardson, TX (US); James R. Todd, Plano, TX (US); Xiaoju Wu, Irving, TX (US)

Correspondence Address: Jacqueline J. Garner, Esq., Texas Instruments Incorporated, P.O. Box 655474, M/S 3999, Dallas, TX, 75265, US

(21) Appl. No.: 09/833,335

(22) Filed: Apr. 12, 2001

(51) Int. Cl. H01L 21/332; H01L 29/76; H01L 29/94; H01L 31/062; H01L 31/113; H01L 31/119; H01L 21/76

(52) U.S. Cl. 257/409; 438/140; 438/454

(57) ABSTRACT

The present invention relates to an NMOS transistor structure which comprises a p-well region in a semiconductor substrate, an n-type source region in the p-well region, and an n-type drain region in the p-well region. The source and drain regions are laterally spaced apart from one another and define a p-type channel region therebetween in the p-well region. The NMOS transistor further comprises a gate having a gate electrode and a gate oxide overlying the channel region of the p-well region. A PDUF region underlies the p-well region and exhibits a resistivity which is less than the p-well region, wherein the PDUF region lowers a resistance associated with the p-well region at high drain voltages. The lowered resistance decreases a gain associated with a parasitic bipolar transistor and increases an injection induced breakdown voltage characteristic of the NMOS transistor structure.

### FIELD OF THE INVENTION

The present invention relates generally to the field of integrated circuits, and more particularly to a MOS transistor structure having an improved injection induced breakdown voltage characteristic.

### BACKGROUND OF THE INVENTION

Transistors are one of several important building blocks in today's integrated circuits. Several different types of transistors are employed in such integrated circuits, for example, MOS type transistors and bipolar type transistors. In many electronic applications, use of both types of transistors are desired to achieve various types of functionality; consequently BiCMOS type semiconductor processes have been developed to accommodate such functionality.

One exemplary MOS transistor structure which is formed in a BiCMOS type semiconductor process is illustrated in prior art FIG. 1, and designated at reference numeral 10. The MOS transistor 10 has several terminals, a gate terminal 12, a source terminal 14, a drain terminal 16 and a backgate terminal 18, respectively. The gate terminal 12 is coupled to a gate electrode 20, for example, a doped polysilicon material, while the source terminal 14 and drain terminal 16 are coupled to n-type diffusion regions 22 and 24 in a semiconductor substrate, respectively. The source and drain regions 22 and 24 reside in a p-type well region 28 within the substrate 26 and is biased by the p-type backgate diffusion contact region 30. The backgate 30 and the source 22 are isolated from one another electrically via a field oxide region 32.

The MOS transistor 10 operates in the following exemplary manner. When a voltage is applied to the gate 12, an electrical field forms in a channel region 34 in the p-well 28, thereby inducing a channel between the source 22, and the drain 24. When a potential is applied across the source and drain terminals 14 and 16, electrons will flow from the source 22 to the drain 24 via the channel 34, and when the voltage is removed from the gate 12, the current flow therethrough is discontinued. In the above manner, the MOS transistor 10 behaves as a voltage controlled switch (or alternatively a voltage controlled variable resistor), wherein a current conduction therethrough is a function of the control voltage at the gate 12. The MOS transistor 10 may be employed to operate in a digital context, wherein the transistor is fully on and approximates a short circuit, or is fully off and approximates an open circuit (e.g., a switch); or the transistor 10 may be employed as a linear device having various controllable modes of operation, as may be desired.

The MOS transistor 10 of prior art FIG. 1 is sometimes employed in high voltage applications, wherein voltages across the drain and source terminals 16 and 14 can reach voltages of 10V or more. Under certain high voltage conditions, the prior art transistor structure 10 may exhibit various forms of undesirable behavior. For example, when the voltage at the drain terminal 16 increases above V_{dsat}=V_{g}−Vₜ when the source terminal 14 is at a circuit ground potential, a substantial amount of substrate current 40 in the form of holes flows from the channel pinch-off region 24 into the p-well region 28, as illustrated in prior art FIG. 2. Such hole current 40 flows through the p-well region 28 as illustrated by arrows 42 and 44 to be collected by the backgate contact 30. The p-well region 28, however, is somewhat resistive, as illustrated by a resistor R_{eff} 46 in prior art FIG. 2.

As the substrate current grows as the drain voltage increases, the resistance R_{eff} 46 causes a voltage drop to develop near a source/p-well junction 48. If the voltage drop at the junction 48 reaches about 0.5V or more, the p-n junction turns on, causing a lateral parasitic NPN bipolar transistor 50 to turn on. That is, a parasitic bipolar device, wherein the drain 24 acts as a collector, the p-well 28 acts as a base, and the source 22 behaves as an emitter, is turned on as illustrated in prior art FIG. 2. Although the parasitic bipolar transistor 50 is a weak device, a substantial amount of leakage current flows, leading to an injection inducted breakdown condition. The drain voltage at which such breakdown occurs is often times referred to as the injection inducted breakdown voltage (BVᵢᵢ). A graph illustrating a BVᵢᵢ rating for the prior art transistor device 10 is illustrated in prior art FIG. 3, wherein BVᵢᵢ is about 20V. That is, when the drain-to-source voltage across the transistor 10 experiences a high voltage condition of about 20V, the parasitic lateral NPN bipolar transistor 50 turns on which contributes to an injection induced breakdown of the device.

High voltage applications need MOS type devices in BiCMOS processes to exhibit BVᵢᵢ characteristics which are better than prior art devices. Accordingly, there is a need in the art for a MOS transistor structure which exhibits an improved injection induced breakdown voltage.

### SUMMARY OF THE INVENTION

The present invention relates generally to an NMOS high voltage transistor structure and an associated method of manufacture, wherein the resulting structure exhibits an improved injection induced breakdown voltage characteristic (BVᵢᵢ) over conventional transistor devices.

According to one aspect of the present invention, an NMOS high voltage transistor structure is disclosed. The NMOS transistor has n-type source and drain regions spaced apart from one another within a p-well region, defining a p-type channel region therebetween. A gate comprising a gate electrode and a gate oxide overlie the channel region to provide a control terminal for the NMOS transistor.

A PDUF region underlies the p-well region in a semiconductor substrate and exhibits a conductivity which is greater than the p-well region, thereby resulting in a retrograde type effective p-well region having a lowered resistance associated therewith compared to conventional devices. At high drain-to-source transistor voltages, transistor current in the form of holes conducts through the retrograde p-well region and is collected by a backgate contact near the source region. Since the effective p-well region (incorporating the PDUF region) exhibits a reduced resistance than conventional devices, the drain-to-source voltage which the transistor can withstand before experiencing an injection induced breakdown condition is increased, for example, from about 20V to about 30V.

According to another aspect of the present invention, the decreased effective p-well resistance of the NMOS transistor structure results in a lowering of a gain associated with a parasitic lateral NPN bipolar transistor which is implicit in the NMOS transistor structure (wherein the drain acts like a collector, the p-well acts like a base, and the source acts like an emitter). The decreased gain associated with the parasitic bipolar transistor causes the parasitic device to remain non-conducting for a larger range of NMOS transistor drain-to-source voltages, thereby providing for an increase in the NMOS transistor injection induced breakdown voltage characteristic.

According to another aspect of the present invention, an NDUF layer is formed under the PDUF layer. In addition, deep n-well regions are formed in the p-well region, and are laterally spaced from the source and drain regions on sides opposite the channel. The deep n-well regions make electrical contact down to the NDUF region, thereby surrounding the NMOS transistor structure in an n-type ring. The n-type ring may then be biased via deep n-well contacts to prevent the NMOS transistor current from being injecting into the underlying semiconductor substrate, thereby preventing any potentially large NMOS transistor currents from affecting other components on the die in which the NMOS transistor resides.

According to still another aspect of the present invention, a drain extension region is formed in the p-well region, and surrounds the drain region associated-therewith. The drain extension region is configured in the p-well region to facilitate high voltages at the drain terminal of the NMOS transistor by reshaping the surface fields associated therewith. Consequently, a substantial portion of the drain region becomes fully depleted as opposed to primarily the channel region experiencing depletion as in conventional transistor structures, thereby increasing the drain-to-source breakdown voltage characteristic (BV_{dss}) associated therewith.

According to still another aspect of the present invention, the NMOS transistor structure includes a lightly doped drain high voltage region laterally contacting the drain region within the drain extension region. The lightly doped drain high voltage region advantageously lowers a resistance associated with the drain extension region, thereby improving an R_{dS(ON)} characteristic associated with the NMOS transistor structure.

To the accomplishment of the foregoing and related ends, the invention comprises the features hereinafter fully described and particularly pointed out in the claims. The following description and the annexed drawings set forth in detail certain illustrative aspects and implementations of the invention. These are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 is a fragmentary cross section diagram illustrating a conventional NMOS transistor structure;

FIG. 2 is a fragmentary cross section diagram illustrating the conventional NMOS transistor structure of FIG. 1, and further illustrating how transistor current in the p-well at high drain voltages can cause a parasitic lateral NPN bipolar transistor implicit in the NMOS transistor structure to turn on;

FIG. 3 is a graph illustrating an injection induced breakdown voltage characteristic associated with conventional NMOS transistor structures such as that illustrated in FIG. 1;

FIG. 4 is a fragmentary cross section diagram illustrating an NMOS transistor structure according to the present invention which exhibits an improved injection induced breakdown voltage characteristic compared to conventional transistor structures;

FIG. 5 is a fragmentary cross section diagram illustrating the NMOS transistor structure of FIG. 4, and further illustrating how a reduction in the resistivity of the effective p-well region due to a PDUF layer thereunder reduces a gain associated with the parasitic lateral NPN bipolar transistor implicit in the NMOS transistor structure, thereby increasing the injection induced breakdown voltage characteristic associated therewith;

FIG. 6 is a graph illustrating an injection induced breakdown voltage characteristic associated with both a conventional NMOS transistor structure and an NMOS transistor structure according to the present invention;

FIG. 7 is a fragmentary cross section diagram illustrating an NMOS transistor structure according to another aspect of the present invention which exhibits an improved injection induced breakdown voltage characteristic compared to conventional transistor structures;

FIG. 8 is a flow chart diagram illustrating a method of forming a high voltage NMOS transistor having an improved injection induced breakdown voltage characteristic according to one exemplary aspect of the present invention; and

FIGS. 9-17 are fragmentary cross section diagrams illustrating various steps in forming a high voltage NMOS transistor in accordance with the method illustrated in FIG. 8.

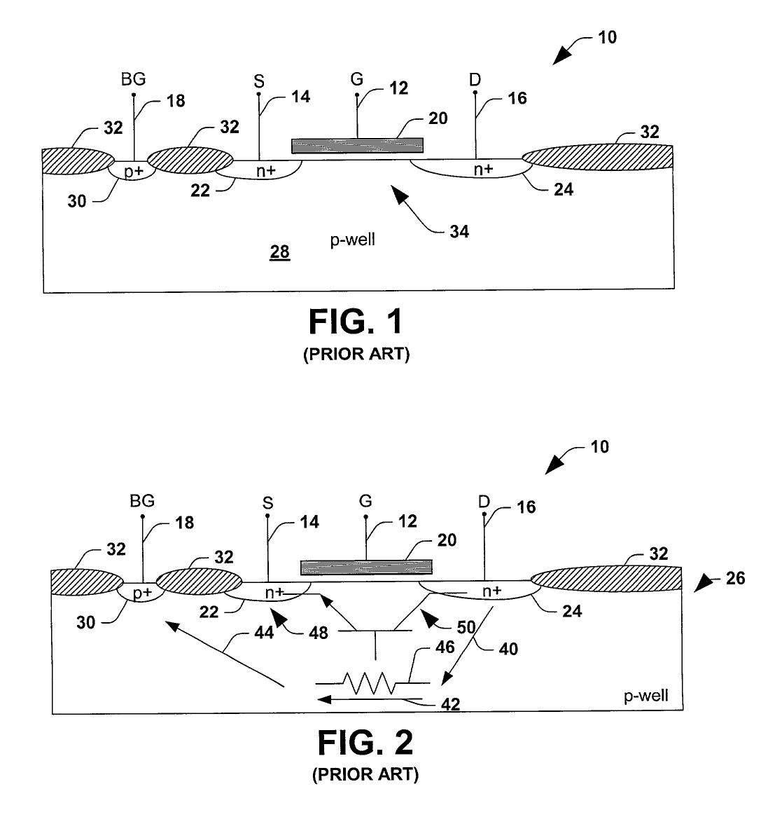

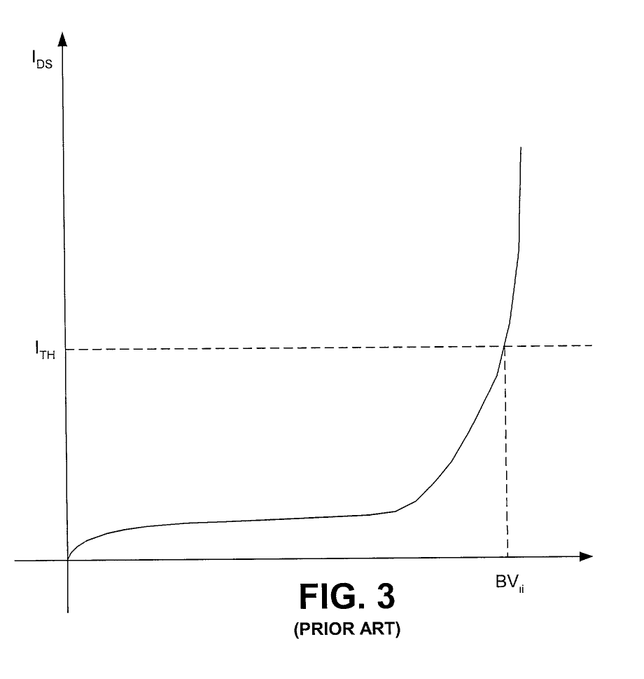

### DETAILED DESCRIPTION OF THE INVENTION

The present invention will now be described with respect to the accompanying drawings in which like numbered elements represent like parts. The present invention is directed to a high voltage NMOS transistor structure and a method of manufacture which exhibits improved injection induced breakdown performance over conventional transistor structures. The NMOS transistor comprises n-type source and drain regions in a p-type p-well region and a p-type PDUF region underlies the p-well region. The PDUF region has a greater dopant concentration than the p-well region and therefore exhibits a lower resistivity, thereby making the two regions collectively appear as a retrograde type p-well region having a lower resistance associated therewith than conventional devices. The PDUF region operates to increase the injection induced breakdown characteristic of the NMOS transistor structure.

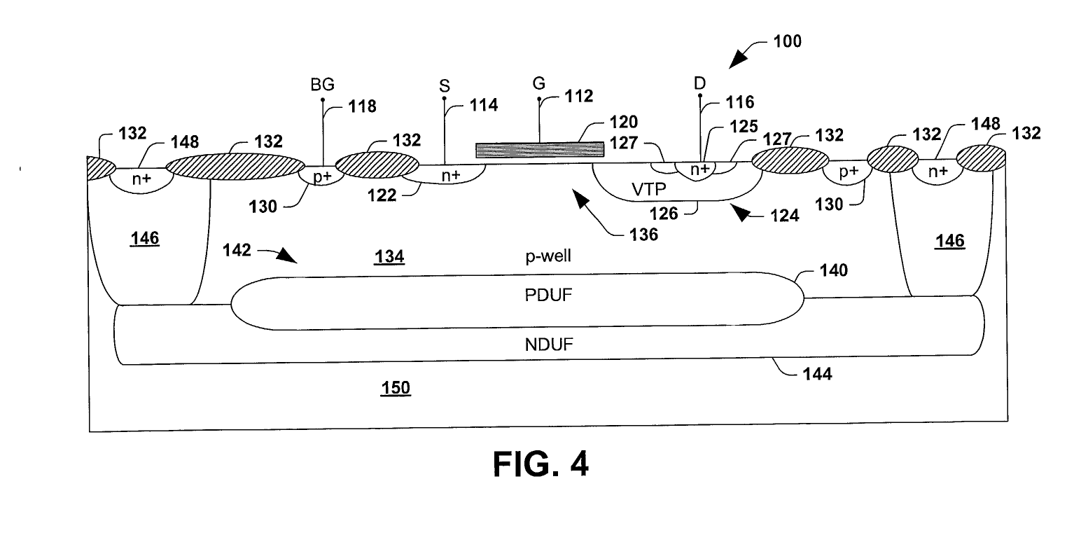

Turning now to the figures, FIG. 4 is a fragmentary cross section diagram illustrating an NMOS transistor structure 100 according to one exemplary aspect of the present invention. The NMOS transistor 100 comprises a gate terminal 112, a source terminal 114, a drain terminal 116, and a backgate terminal 118 as illustrated. The gate terminal 112 couples to a gate electrode 120 (e.g., a polysilicon type gate electrode) which overlies a gate oxide. The source terminal 114 is coupled to an n-type source region 122 and the drain terminal 116 is coupled to a drain region 124. According to one exemplary aspect of the present invention, the drain region 124 further comprises a drain contact region 125 embedded within a drain extension region 126. In addition, lightly doped drain high voltage regions 127 are formed laterally next to the drain contact region 125, as illustrated.

Continuing with FIG. 4, backgate contact regions 130 are provided laterally spaced apart from the source region 122 and the drain region 124, respectively, via field oxide regions 132. The source and drain regions 122 and 124 are formed in a p-type p-well region 134 and the lateral distance between the source 122 and the drain 124 defines a channel region 136 therebetween which underlies the gate 120. A p-type PDUF region 140 underlies the p-well region 134, and for reasons that will be described in greater detail infra, exhibits a p-type dopant concentration which is greater than that of the p-well region 134, thereby making the PDUF region 140 less resistive (i.e., more conductive) than the overlying p-well 134. Therefore the p-well region 134 and the PDUF region 140 together form an effective p-type retrograde well region 142, wherein the dopant concentration is greater at a bottom portion thereof.

Still continuing with FIG. 4, an n-type NDUF region 144 underlies the PDUF region 140. Deep n-well regions 146 make electrical contact down to the NDUF region 144, for example, as illustrated. The deep n-well regions 146 have n-well contact regions 148 associated therewith. The deep n-well regions 146 along with the NDUF region 144 form an n-type ring or tub which surrounds the p-well 134. By biasing the n-type ring via the n-well contact regions 148, transistor current may be prevented from being injected into an underlying semiconductor substrate 150, as will be described later in greater detail.

The transistor 100 of FIG. 4, in accordance with one exemplary aspect of the present invention, operates in the following manner, and will be discussed in conjunction with FIGS. 4-6. The NMOS transistor 100 is a high voltage device which is operable to withstand larger drain-to-source voltages than standard NMOS type devices. The drift region 126 is employed to limit the lateral field strength when the transistor 100 is non-conducting (or off) to a field strength value that is below an avalanche breakdown threshold of the p-n junction thereat. To maximize this high voltage capability, the extension region may be made long and/or very lightly doped. However, both characteristics (a long extension region and a light doping concentration) may result in an increase in the transistor's on resistance (R_{DS(ON))}.

To minimize the design trade-off between breakdown voltage and R_{DS(ON)}, the extension region 126 of the present invention uses a reshaped or reduced surface field effect (RESURF). By diffusing the extension region with an appropriate doping profile and/or adjusting its depth, the reverse biased junction between the channel and the drain depletes substantially the entire extension region 126 of charge carriers, which creates a uniform electric field in the extension region. The creation of a uniform electric field in the extension region 126 improves the avalanche breakdown characteristic of the device because there are substantially no peaks in the electric field to initiate a premature avalanche breakdown. It was found that the extension region 126 so formed having a doping concentration of about 2×10¹⁷/cm³ exhibited a BV_{dss} of about 32V compared to a traditional NMOS transistor structure which exhibited a BV_{dss} of only about 13V.

Continuing with the discussion of the operation of the transistor structure 100, when one wishes to activate the NMOS transistor, a gate-to-source bias potential is applied to the device which is greater than the transistor threshold voltage, causing the channel region 136 to invert, and electrons to travel therethrough from the source 122 to the drain 126. For high drain voltages, a substantial amount of current in the form of holes is injected into the p-well region from the drain 124 and is then collected via the backgate contacts 130.

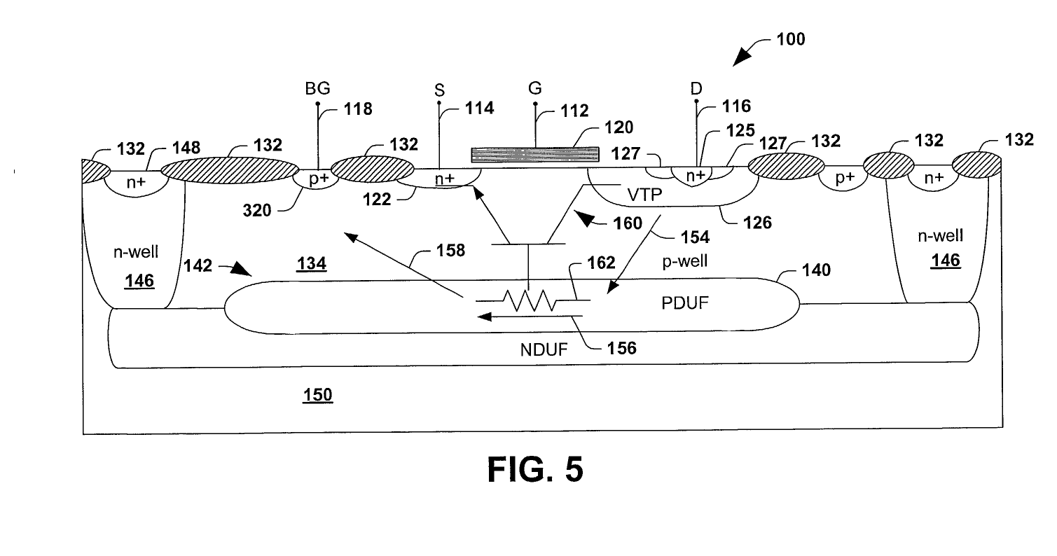

As the hole current, which a portion may travel through the p-well region 134 at arrows 154, 156 and 158 of FIG. 5, respectively, increases at higher voltage levels, a voltage drop appears at the p-n junction formed by the source 122 and the p-well 134. If the voltage drop at this junction reaches about 0.5V or so, the junction turns on, thereby causing the parasitic NPN bipolar transistor 160 illustrated in FIG. 5 to turn on. The activation of the parasitic bipolar device 160 leads to the injection induced breakdown condition.

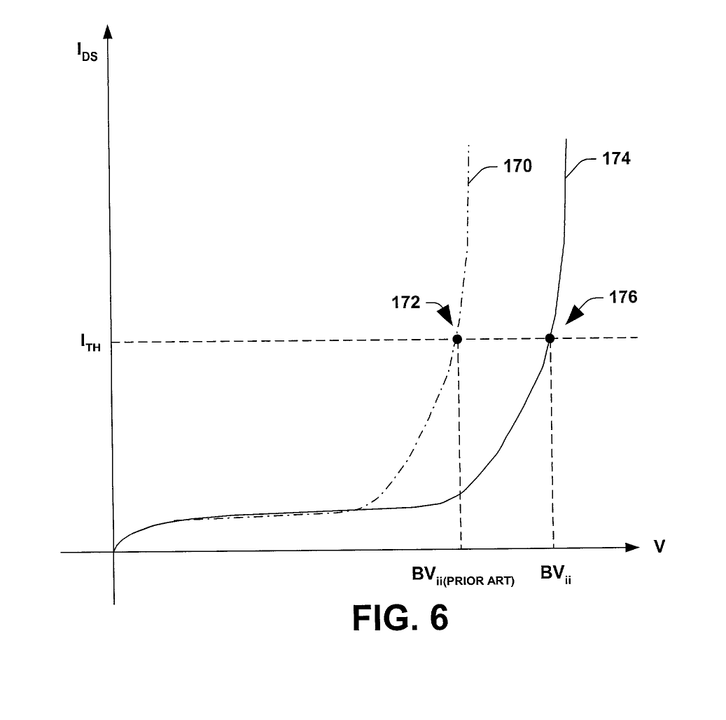

According to the present invention, the PDUF region 140 exhibits a lower resistance than the p-well region 134 due to its higher doping concentration of about 5×10¹⁷/cm³ compared to the p-well concentration of about 5×10¹⁶/cm³. Therefore the PDUF 140 and the p-well together form a retrograde type p-well region 142 that exhibits a lower effective resistance162 than conventional devices. Since the retrograde well 142 exhibits a lower resistance, the drain voltage may get substantially higher before the hole current associated therewith is sufficiently large to turn on the source/p-well junction (since V=IR, if R decreases, I must increase to reach a voltage drop of about 0.5V or so). Looking at the phenomena of the additional PDUF region 140 another way, the decreased resistance of the retrograde well 142 reduces the gain associated with the parasitic bipolar device 160. With a reduction in gain, the “collector” voltage (i.e., the drain voltage) must substantially increase for any substantial conduction to occur. In the above manner, the PDUF region 140 operates to improve the injection induced breakdown characteristic (BVᵢᵢ) of the transistor 100, for example, from about 20V in conventional high voltage devices to about 30V, as illustrated in the graph of FIG. 6.

As seen in FIG. 6, a first waveform 170 represents an injection induced breakdown voltage characteristic for a conventional high voltage transistor device. Note that with the waveform 170, the drain-to-source current (I_{DS}) increases above a threshold current value (I_{TH}) at a location 172, which corresponds to a BVᵢᵢ of about 20V. In the graph of FIG. 6, the threshold I_{TH} is selected to be about 1.5*I_{DSAT} when V_{GS}>Vₜ. As is well known by those skilled in the art, slightly different curves will be generated for varying transistor gate-to-source voltages. The curves illustrated in FIG. 6 both represent transistor characteristics under approximately the same V_{GS} conditions.

FIG. 6 also illustrates a waveform 174 which represents the injection induced breakdown characteristic of a transistor structure according to the present invention, for example, the NMOS transistor structure 100 of FIG. 4. Note that in the waveform 174, the drain-to-source current I_{DS} increases above the current threshold I_{TH} at another point 176 which corresponds to a different voltage (e.g., about 30V) which is substantially greater than the BVᵢᵢ of conventional devices, thereby illustrating the improvement in the injection induced breakdown voltage characteristic exhibited by the NMOS transistor structure of the present invention.

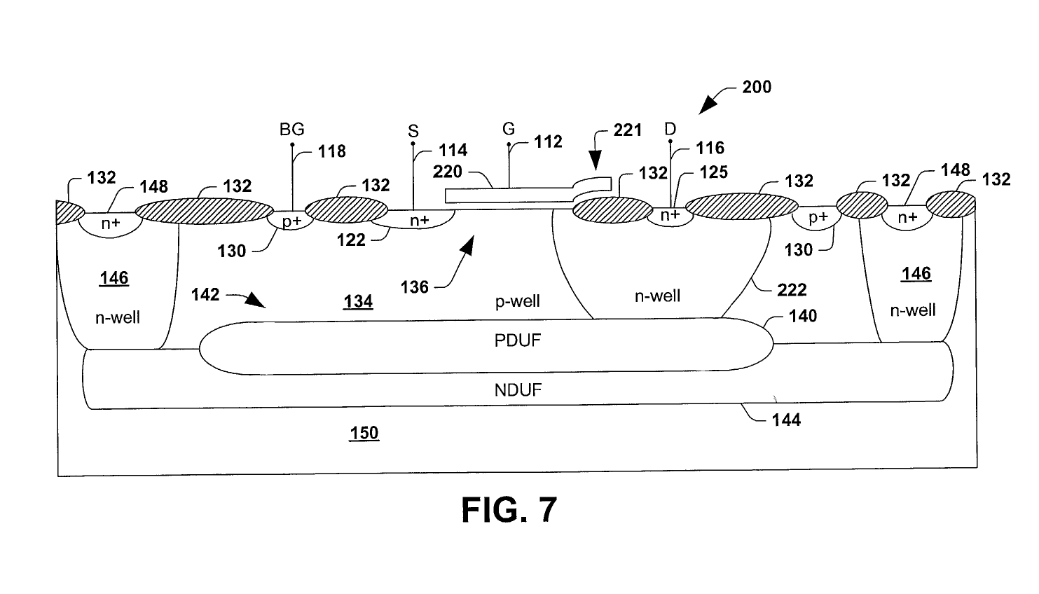

According to another aspect of the present invention, an NMOS transistor structure is illustrated in FIG. 7, and is designated at reference numeral 200. In the NMOS transistor structure 200, the gate electrode 120 is replaced with a different gate electrode 220 that has a field plate portion 221 which overlies a portion of a field oxide region 132. In addition, the drain extension region 126 of FIG. 4 is removed and replaced with a deep n-well region 222 that makes electrical contact down to the PDUF region 140. In the transistor structure 200, no extension region is employed as in FIG. 4 to shape the surface fields; instead, the gate electrode portion 221 acts as a field plate that serves to influence the electric field shape in at least a portion of the deep n-well region 222 at large drain voltages. Due to the presence of the PDUF region 140, the transistor also exhibits an improved injection induced breakdown voltage characteristic (BVᵢᵢ) over conventional devices.

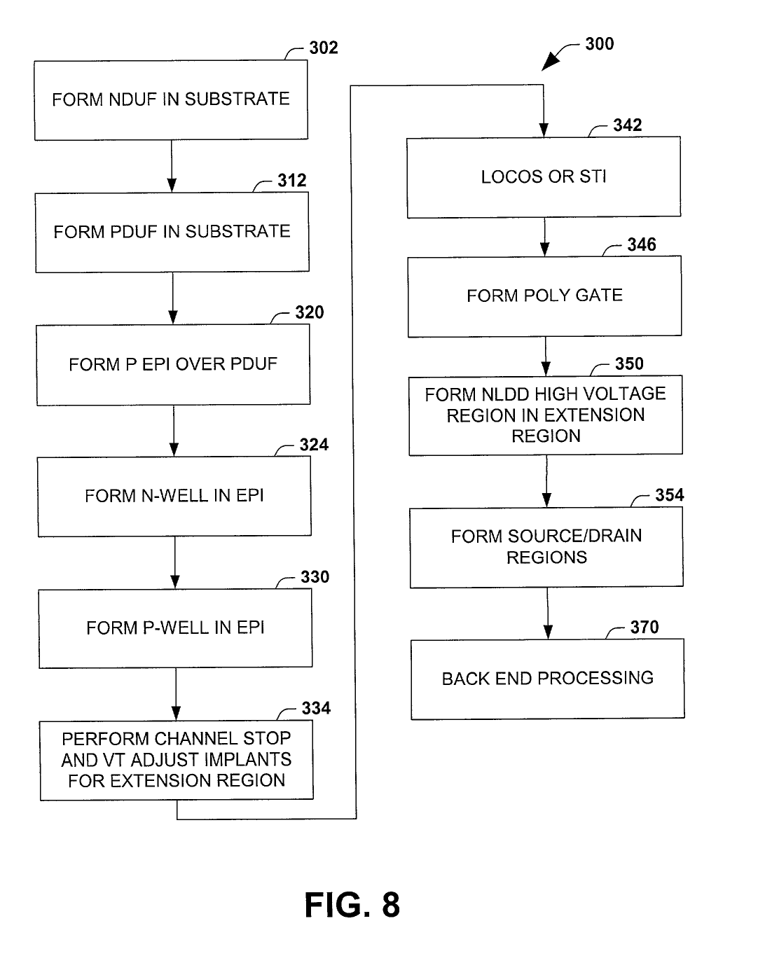

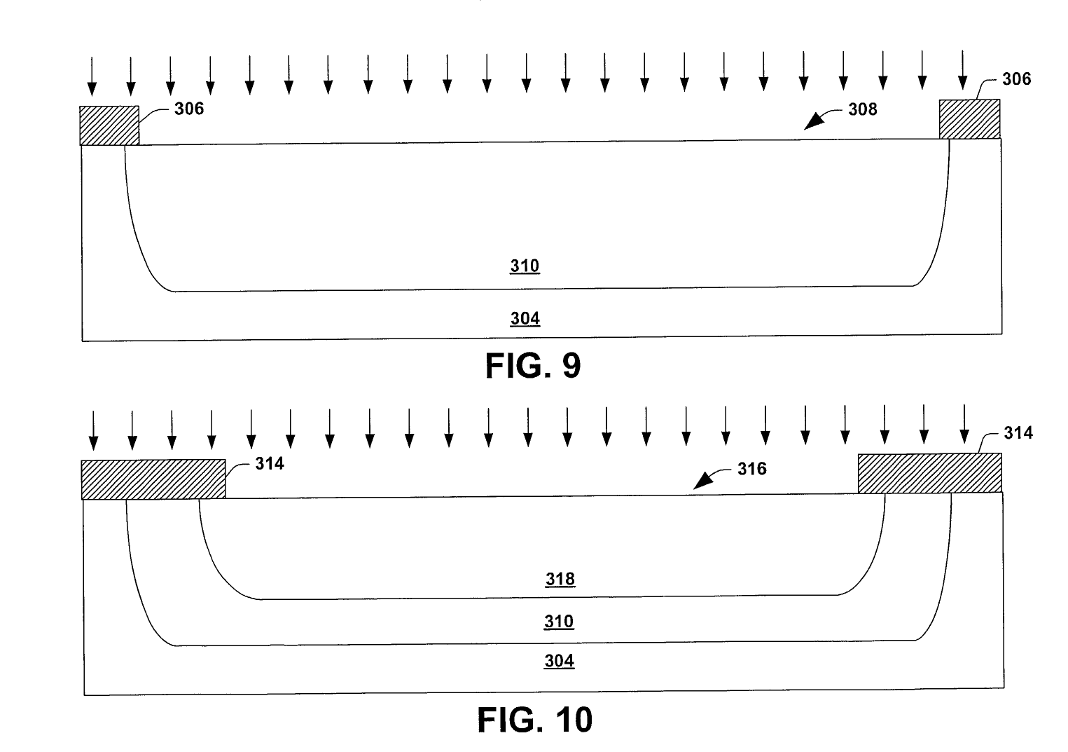

According to yet another aspect of the present invention, a method of forming a high voltage NMOS transistor structure is disclosed, as illustrated in FIG. 8 and designated at reference numeral 300. The various steps in the flow chart of FIG. 8 will be described in conjunction with the exemplary cross section diagrams of FIGS. 9-17 for purposes of illustration, however, it should be understood that variations in the steps, a re-ordering of various steps or the elimination of one or more steps may occur and such variations are contemplated as falling within the scope of the present invention.

The method 300 begins at step 302 by forming an n-type NDUF region is a semiconductor substrate. For example, as illustrated in FIG. 9, a substrate such as a lightly doped p-type substrate 304 may be masked by a photoresist 306 and a portion 308 thereof is selectively implanted with an n-type dopant to form an n-type tank 310 which will form the NDUF region. According to one exemplary aspect of the present invention, the implantation comprises implanting antimony with a dose of about 5×10¹⁵/cm² at an implantation energy of about 150 keV to form the tank 310 with a dopant concentration of about 1×10¹⁹/cm³. Alternatively, other n-type dopants such as arsenic or phosphorous may be employed and are contemplated as falling within the scope of the present invention.

The method 300 of FIG. 8 continues at step 312, wherein a p-type PDUF region is formed in the substrate, for example, as illustrated in FIG. 10. For example, a photoresist 314 is formed on the substrate 304 to define a region 316 to be subjected to implantation. The region 316 is then implanted with a p-type dopant, for example, boron, with a dose of about 8×10¹³/cm² at an implantation energy of about 60 keV to form a p-type tank 318 having a dopant concentration of about 5×10¹⁷/cm³.

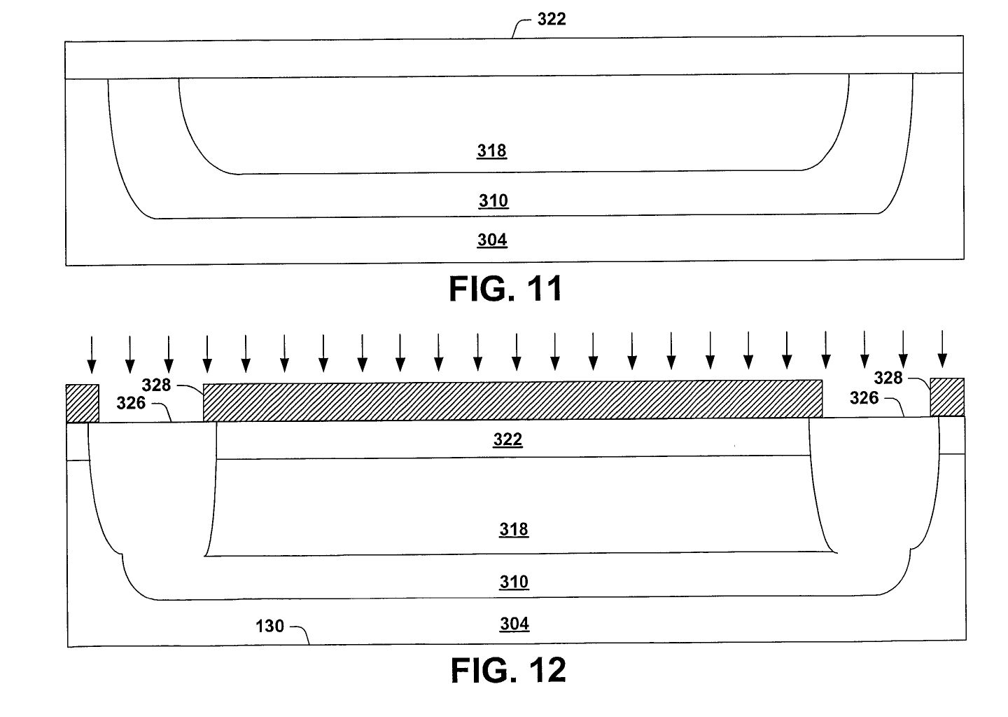

The method 300 of FIG. 8 continues at step 320 by forming a p-type epitaxial layer over the surface of the semiconductor substrate 304. For example, as illustrated in FIG. 11, an epitaxial layer 322 may be formed, for example, via chemical vapor deposition (CVD) as an intrinsic silicon layer and subsequently doped via ion implantation, or alternatively doped with a p-type dopant in-situ. According to one aspect of the invention, the layer 322 is formed as an intrinsic silicon layer and doped to form a p-well region at a later processing step, as will be described infra.

The method 300 of FIG. 8 continues at step 324 by forming a plurality of n-well regions, as illustrated in FIG. 12 and designated at reference numeral 326. For example, step 324 may include masking off portions of the die with a photoresist 328 and then performing an implantation using an n-type dopant such as phosphorous. For example, the implantation may comprise a high energy implant having a dose of about 1×10¹³/cm² and an implantation energy of about 150 keV to drive the n-well regions 326 down deep to make electrical contact down to the NDUF region 310. The n-well regions 326 may have a resultant dopant concentration of about 7×10¹⁶/cm³. The n-well regions 326 along with the NDUF region 310 form an n-type ring that surrounds or encompasses the transistor and may be used under biased conditions to prevent transistor current from being injected into the substrate 304.

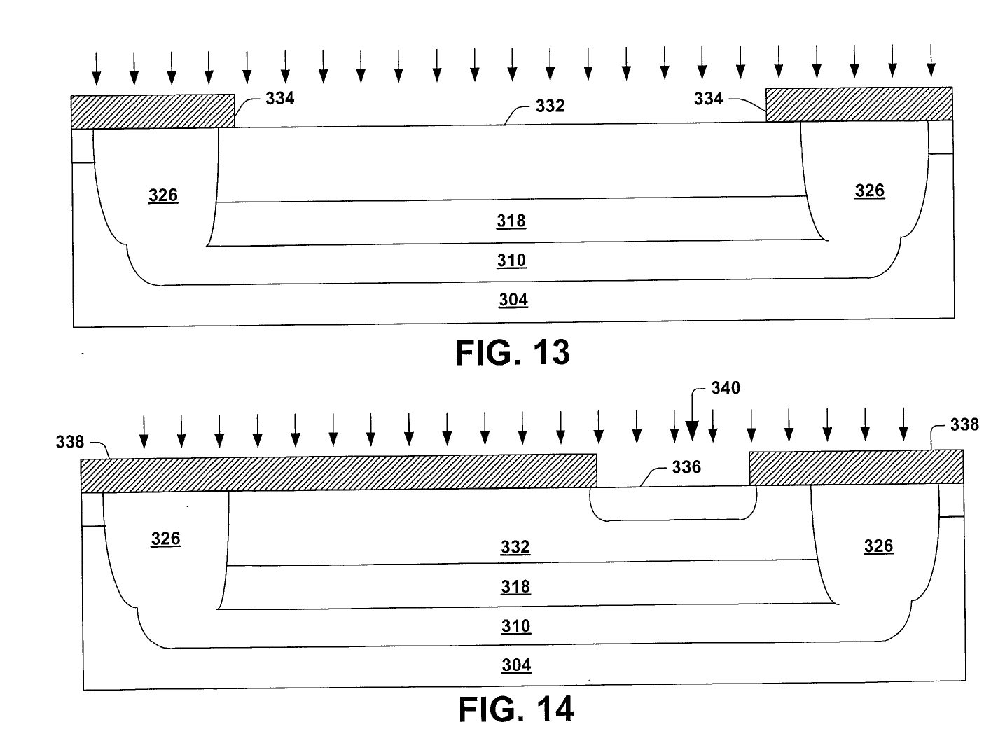

The method 300 of FIG. 8 continues at step 330, wherein the p-well region is formed in the epi layer 322 as illustrated in FIG. 13 and designated at reference numeral 332. The p-well region 332 may be formed by masking off portions of the die surface with a photoresist 334 and implanting an exposed area 336 with a p-type dopant. For example, the p-well 332 may be formed with a p-type dopant such as boron at a dose of about 6×10¹²/cm² and an implantation energy of about 40 keV to form a region having a dopant concentration of about 5×10¹⁶/cm³. Note that in FIG. 13, the p-well region 332 is shown diffusing into a portion of the PDUF region 318, however, this diffusion may be minimized or otherwise altered via the implantation energy, as may be desired.

The method 300 of FIG. 8 further continues at step 334, wherein a drain extension region is formed, as illustrated in FIG. 14 and designated at reference numeral 336. According to one exemplary aspect of the present invention, the drain extension region 336 may be formed with two distinct implants, namely using a channel stop implant and a Vₜ adjust implant which are typically employed in standard BiCMOS type processes. For example, as illustrated in FIG. 14, a photoresist mask 338 may be employed to define a portion 340 to be implanted. A first implantation dose may be, for example, 1.6×10¹²/cm² at an implantation energy of about 50 keV, and a second implant may have a dose of about 5×10¹²/cm² at an implantation energy of about 150 keV. The resulting drain extension region 336 has a depth and doping concentration profile (e.g., about 2×10¹⁷/cm³ in a portion thereof) that facilitates a reshaping of the surface fields at high drain voltages, thereby improving the transistor BV_{dss}, as described supra.

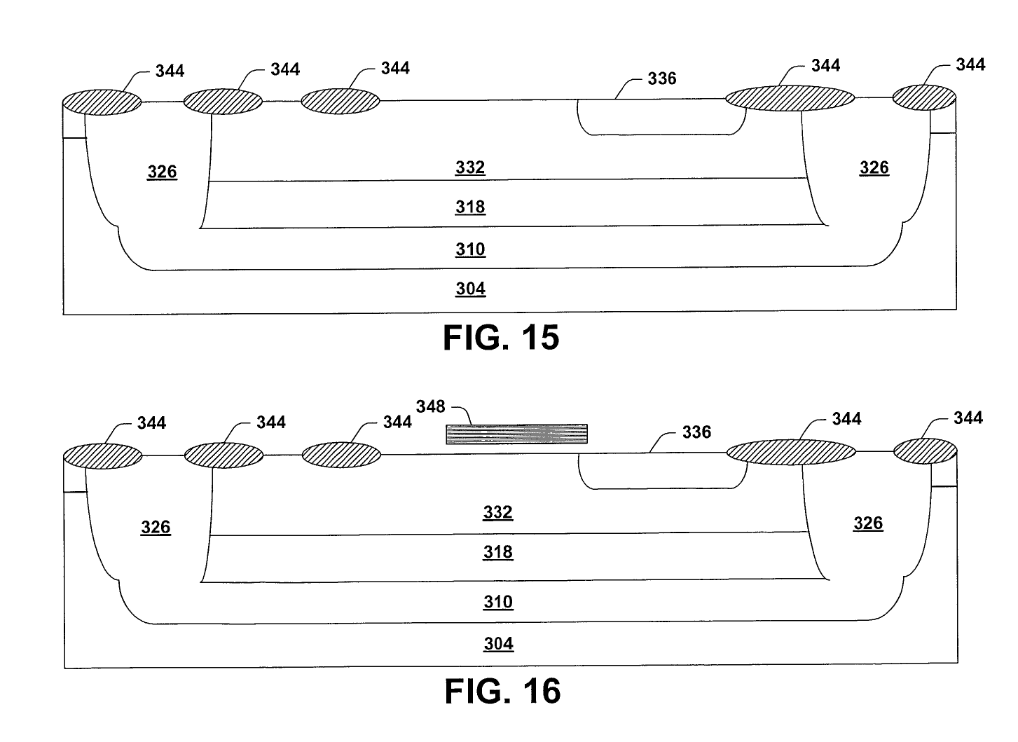

The method 300 of FIG. 8 continues at step 342, wherein isolation is provided on a surface of the substrate using, for example, conventional LOCOS or shallow trench isolation (STI) techniques, as may be desired. Such isolation results in insulating regions 344 on various portions of the substrate, as illustrated in FIG. 15. The method 300 then continues at step 346, wherein a polysilicon film is deposited, for example, via CVD and either doped in situ or subsequently doped to decrease the resistance thereof. The polysilicon film is then patterned, for example, via a dry plasma etch to define a polysilicon gate 348 over the p-well 332, as illustrated in FIG. 16.

Returning to FIG. 8, the method 300 continues at step 350, wherein a lightly doped drain high voltage region 352 is formed in the drain extension region via, for example, ion implantation with an n-type dose between about 1×10¹²/cm² and about 5×10¹²/cm² with an implantation energy of about 50 keV, thereby resulting in a region having a dopant concentration of about 5×10¹⁷/cm³. As discussed supra, the lightly doped drain high voltage region 352 reduces a resistance associated with the drain extension region 336, thereby advantageously reducing an RDS(ON) associated with the resulting transistor.

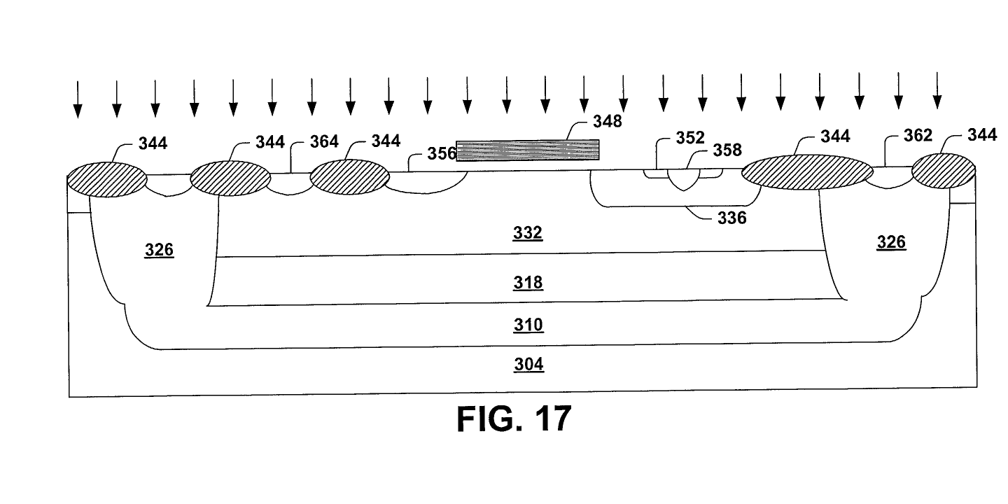

At step 354 of FIG. 8, the method 300 continues with the formation of the source and drain regions, respectively, as illustrated in FIG. 17 and designated at reference numerals 356 and 358, respectively. In addition, the step 354 may also be used to form n-well contact regions 360 and 362, respectively. A subsequent implantation may be employed to generate a backgate contact region 364 for the p-well 332. The method 300 then concludes with any additional back end processing, for example, metallization, etc. to coupled the resulting high voltage NMOS transistor to other IC circuitry as may be desired.

The method 300 of FIG. 8 provides for a high voltage NMOS transistor which exhibits an improved injection induced breakdown voltage characteristic due to the inclusion of a low resistance PDUF layer under the p-well. Consequently, a substantially greater amount of substrate type hole current is necessary to activate the source/p-well pn junction. Therefore larger drain voltages may be accommodated prior to the transistor experiencing an injection induced breakdown condition. Therefore the BVᵢᵢ of the transistor is improved over the prior art.

In addition, the transistor of method 300 in FIG. 8 employs a drain extension region to provide a RESURF operation to improve a BV_{dss} thereof. Alternatively, the method of the present invention contemplates using the n-well implant to generate an n-type drain extension type region that makes contact down to PDUF. This and other alterations may be made and such alternatives are contemplated as falling within the scope of the present invention.

Although the invention has been shown and described with respect to a certain aspect or various aspects, it is obvious that equivalent alterations and modifications will occur to others skilled in the art upon the reading and understanding of this specification and the annexed drawings. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several aspects of the invention, such feature may be combined with one or more other features of the other aspects as may be desired and advantageous for any given or particular application. Furthermore, to the extent that the term “includes” is used in either the detailed description or the claims, such term is intended to be inclusive in a manner similar to the term “comprising.”

What is claimed is:

1. An NMOS transistor structure, comprising:
a p-well region in a semiconductor substrate;
an n-type source region in the p-well region;
an n-type drain region in the p-well region and laterally spaced apart from the source region defining a p-type channel region therebetween in the p-well region;
a gate comprising a gate electrode and a gate oxide overlying the channel region of the p-well region; and
a PDUF region underlying the p-well region, wherein the PDUF region exhibits a resistivity which is less than the p-well region, wherein the PDUF region lowers a resistance associated with the p-well region at high drain voltages, thus lowering a gain associated with a parasitic bipolar transistor, and thereby increasing an injection induced breakdown voltage characteristic of the NMOS transistor structure.

2. The NMOS transistor structure of claim 1, further comprising an n-type ring surrounding the NMOS structure and underlying the PDUF region, wherein the n-type ring is biased to prevent NMOS transistor current from being injected into the semiconductor substrate.

3. The NMOS transistor structure of claim 1, wherein the n-type ring comprises:
an NDUF region underlying the PDUF region;
a first deep n-well region in the p-well region and laterally spaced apart from the source region opposite the channel, and making electrical contact down to the NDUF region; and
a second deep n-well region in the p-well region and laterally spaced apart from the drain region opposite the channel region, and making electrical contact down to the NDUF region,
wherein the first and second deep n-well regions have contact portions associated therewith for coupling an electrical potential thereto for biasing the n-type ring with respect to the p-well region to thereby prevent NMOS transistor current from being injected into the semiconductor substrate.

4. The NMOS transistor structure of claim 1, wherein the n-type drain region further comprises:
an n-type drain contact region; and
an n-type drain extension region surrounding the drain contact region, and operable to allow a relatively large drain voltage to be applied to the drain contact region without experiencing a drain-to-source breakdown condition.

5. The NMOS transistor structure of claim 4, wherein the n-type drain extension region has a predetermined shape and a dopant concentration to reshape surface fields therein when drain voltages are applied thereto, thereby allowing a substantial portion thereof to deplete before the drain extension region breaks down, thereby improving a breakdown voltage characteristic of the NMOS transistor structure.

6. The NMOS transistor structure of claim 5, wherein the drain extension region has a dopant concentration of about 2×10¹⁷/cm³.

7. The NMOS transistor structure of claim 4, wherein the n-type drain extension region further comprises a lightly doped drain high voltage region formed in the n-type extension region, and contacting the drain contact region on a channel side thereof, wherein the lightly doped drain high voltage region reduces a resistance associated with the drain extension region.

8. The NMOS transistor structure of claim 7, wherein the lightly doped drain high voltage region has a dopant concentration of about 5×10¹⁷/cm³.

9. The NMOS transistor structure of claim 1, wherein the PDUF region has a dopant concentration of about 5×10¹⁷/cm³.

10. The NMOS transistor structure of claim 9, wherein the p-well region has a dopant concentration of about 5×10¹⁶/cm³.

11. The NMOS transistor structure of claim 1, wherein the drain region comprises a deep n-well region which extends down to the PDUF region, and wherein the gate electrode extends over a substantial portion of the deep n-well region, thereby acting as a field plate and influencing an electric field in the deep n-well region at relatively high drain voltages.

12. A method of forming an NMOS high voltage transistor structure, comprising the steps of:
forming a p-type PDUF region having a first resistivity associated therewith in a semiconductor substrate;
forming a p-type p-well region having a second resistivity which is greater than the first resistivity over the PDUF region;
forming n-type source and drain regions in the p-well region, wherein a lateral spacing between the source and drain regions defines a channel region in the p-well region; and
forming a gate having a gate electrode and a gate oxide over the channel region,
wherein the PDUF region and the p-well region form a p-type retrograde well which reduces a resistivity associated therewith, thereby increasing an injection induced breakdown voltage characteristic associated therewith.

13. The method of claim 12, further comprising forming an n-type NDUF region in the semiconductor substrate prior to forming the PDUF, thereby causing the PDUF region to overlie the NDUF region in the semiconductor substrate.

14. The method of claim 13, wherein forming the NDUF region comprises selectively implanting a portion of the semiconductor substrate with antimony, arsenic or phosphorous at a dose of about 5×10¹⁵/cm² at an implantation energy of about 150 keV.

15. The method of claim 13, further comprising forming two laterally spaced apart n-well regions on opposite sides of the p-well region, and making electrical contact down the NDUF region, thereby forming an n-type ring surrounding the p-well and PDUF regions.

16. The method of claim 12, wherein forming the p-well region comprises:
forming an epitaxial silicon layer over the semiconductor substrate after forming the PDUF region; and
doping a portion of the epitaxial silicon layer with a p-type dopant.

17. The method of claim 16, wherein doping the epitaxial silicon layer comprises implanting boron therein to generate a dopant concentration of about 5×10¹⁶/cm³.

18. The method of claim 12, wherein forming the drain region comprises selectively implanting an n-type dopant into a portion of the p-well region, thereby forming a drain extension region having a length and doping concentration associated therewith that causes the drain region to deplete substantially uniformly and substantially completely prior to experiencing an avalanche breakdown condition, thereby increasing an avalanche breakdown characteristic of the transistor.

19. The method of claim 18, wherein forming the drain extension region comprises:
selectively implanting an n-type dopant into a portion of the p-well region with a dose of about 1.6×10¹²/cm² at an implantation energy of about 50 keV; and
selectively implanting an n-type dopant into generally the same portion of the p-well region with a dose of about 5×10¹²/cm² at an implantation energy of about 150 keV.

20. The method of claim 19, wherein the n-type dopant for the implantation steps of the drain extension region comprises phosphorous.

21. The method of claim 18, wherein forming the drain region further comprises:
selectively implanting a portion of the drain extension region with an n-type dopant, thereby forming a lightly doped drain high voltage region therein; and
selectively implanting a portion of the lightly doped drain high voltage region with an n-type dopant, thereby forming a drain contact region therein, wherein the lightly doped drain high voltage region reduces a resistance associated with the drain extension region.

22. The method of claim 21, wherein forming the lightly doped drain high voltage region comprises implanting the portion of the drain extension region with phosphorous having a dose of about 1×10¹²/cm² to about 5×10¹²/cm² with an implantation energy of about 50 keV.
